(19) United States
(12) Patent Application Publication
(10) Pub. No.: US 2005/0184304 A1
(43) Pub. Date: Aug. 25, 2005

(54) Large cavity wafer-level package for MEMS

(76) Inventors: Pavan O. Gupta, Belmont, CA (US); Paul M. Hagelin, Saratoga, CA (US); Gregory Andronaco, Palo Alto, CA (US)

Correspondence Address: SAWYER LAW GROUP LLP, P.O. Box 51418, Palo Alto, CA, 94303, US

(21) Appl. No.: 10/787,509

(22) Filed: Feb. 25, 2004

(51) Int. Cl. H01L 33/00

(52) U.S. Cl. 257/98; 257/434

(57) ABSTRACT

The invention provides a wafer-level package for a micromirror array. The wafer-level package includes a substrate including a wafer having a substrate surface with a plurality of actuatable micromirrors coupled to the substrate surface. An optical window is attached to the substrate surface to form at least one sealed cavity between an inner surface of the optical window and the substrate surface. A beam of light transmitted through the optical window is redirected by at least one actuatable micromirror within the sealed cavity.

### FIELD OF THE INVENTION

The present invention relates generally to optical switches and beam-steering devices, and more specifically to wafer-level packages with large cavities for MEMS micromirror arrays.

### BACKGROUND OF THE INVENTION

Photonic, optical and micromechanical devices are typically packaged so that active elements such as micromirrors are disposed within a sealed chamber to protect them from handling, mechanical, environmental, or other damage. Existing packaging systems for microelectromechanical systems (MEMS) devices, which are based on commercially available military hybrid packages and multi-layer ceramic packages, include hermetically sealed chambers to prevent the influx, egress or exchange of gases, moisture and particulates between the chamber and the environment. With optical systems, hermetic sealing is particularly critical to the long-term stability of active optical components, which can be affected by humidity and other environmental factors that can degrade device performance. Therefore, encapsulating the device in a vacuum or a controlled ambient is often necessary.

Micromirrors and other moving components of MEMS or micro-optical-electromechanical systems (MOEMS) generally impose further constraints to package designs, such as requiring electrostatic discharge protection. Additionally, optically active devices, such as mirrors, light-emitting devices or photoreceptors, often require at least a portion of the package to be transparent to light or other electromagnetic energy such as visible light, infrared light, and ultraviolet light. In the case of movable devices such as a micromirror assembly, the package needs a cavity deep enough to accommodate relatively large deflections of the micromirrors and associated actuators.

An exemplary optical MEMS device contains electronically controllable movable optical mirrors that are micromachined from a silicon wafer or thin films deposited upon a substrate, and coated with various materials to produce a reflective mirror surface. The mirror structure may be bonded within a preformed cavity of a conventional ceramic or plastic package. In current art, a cap or cover having an optically transparent window is bonded to the conventional package over the MEMS device. Although the window is commonly glass, other proposed window materials include quartz, sapphire, and polycarbonate plastics. The windowed encapsulating cover allows light to pass to and from the optical mirrors, and protects the fragile mirrors from handling and environmental concerns.

Hermetically sealed and windowed packages are described in “Hermetically Sealed Transducer and Methods for Producing the Same,” Kurtz et al., U.S. Pat. No. 6,326,682 granted Dec. 4, 2001; “MEMS Device Wafer-Level Package,” Kocian et al., U.S. Patent Application No. 2003/0211654 published Nov. 13, 2003; and “Single Level Microelectronic Device Package with an Integral Window,” Peterson et al., U.S. Pat. No. 6,661,084 granted Dec. 9, 2003.

In one example, a hybrid ceramic package with a transparent window is used to enclose a MEMS device for mounting on a polymer printed wiring board, as described in “Packaging Micromechanical Devices,” Low et al., U.S. Pat. No. 6,603,182 issued Aug. 5, 2003. The main interconnection and routing function is implemented using standard low-cost epoxy printed circuit technology.

In another example, a package may include a window and a weldable frame, each having metallized ring areas that form a hermetic seal circumscribing the window when in contact with one another and heated, as described in “Hermetically Sealed Micro-Device Package with Window,” Stark, U.S. Pat. No. 6,627,814 issued Sep. 30, 2003. A package using an all-silicon chamber for mechanically isolating a MEMS device may be attractive, as suggested in “Packaging Micromechanical Devices,” Degani et al., U.S. Pat. No. 6,433,411 granted Aug. 13, 2002.

Integrated packages are being developed to reduce cost and improve handling capability of MEMS die. Generally, materials used for integrated MEMS packages need to have similar coefficients of thermal expansion (CTE) so that stress mismatches generated over temperature are minimized. Anti-reflective coatings may be applied to the window to improve light transmission. A wafer-level packaging process for MEMS applications using silicon-on-insulator (SOI) wafers is described in “Wafer-Level Through-Wafer Packaging Process for MEMS and MEMS Package Produced Thereby,” Brady, U.S. Pat. No. 6,660,564 granted Dec. 9, 2003.

The cap or cover should reduce or eliminate electrostatic charge buildup that could degrade the positional accuracy and stability of the mirrors. Applications in which electrically conductive surfaces are required on optically transparent windows are particularly challenging since most conductive materials are opaque. One proposed conductive package has an electrically conductive film covering its surface areas, allowing grounding of the package. An optically transparent conductive material is described in “Static Dissipation Treatments for Optical Package Windows,” Martin et al., U.S. Patent Application 2003/0179986 published Sep. 25, 2003. The electrically continuous film of the optically transparent conductive material can be antireflective, with minimal optical transmission loss. Conductive spacer walls as part of a package for an actuatable MEMS device are described in “Packaged MEMS Device and Method for Making the Same,” Carr et al., U.S. Pat. No. 6,519,075 granted Feb. 11, 2003.

While packages have been designed to provide electrostatic isolation, not many have a sufficient height for movable and actuatable MEMS devices, as pointed out in “Resiliently Packaged MEMS Device and Method for Making Same,” Jin et al., U.S. Patent Application No. 2002/0097952 published Jul. 25, 2002.

Besides the walls of a package needing to be hermetic and conductive, the bonding of a lid over a MEMS device on a wafer needs good hermetic and conductive properties. For example, some adhesives and polymers cannot be used in MEMS packages because they are neither conductive nor hermetic. The weak environmental and heat-resistance properties of many MEMS devices such as micromirrors need to be taken into consideration when selecting the most appropriate sealing process. Methods for sealing the MEMS devices include wafer-level bonding and a chip-level sealing. One method for hermetically sealing a MEMS device within a cavity is suggested in “MEMS Wafer Level Package,” Orcutt et al., U.S. Pat. No. 6,452,238 issued Sep. 17, 2002. The cavity is formed by bonding a silicon wafer with active circuits to an etched silicon wafer having cavities that surround each device, and bonding the two wafers by either a thin-film glass seal or by a solder seal.

Some of the more common wafer bonding techniques that have been used for MEMS devices include low-melting temperature eutectic bonding, anodic bonding, thermocompression bonding, and adhesive bonding. Eutectic bonding uses a solder of an alloy that moves from completely molten to a solid phase as the bonding temperature is dropped to provide good sealing and conductive properties. Anodic bonding, a method of hermetically and permanently joining glass to silicon without the use of adhesives, is a high-temperature process and requires flat, smooth mating surfaces. The glass alone does not provide a conductive package to prevent electrostatic discharge. Bonding by thermocompression requires heating the package to high temperatures that may damage the MEMS or other on-chip devices. Bonding with adhesives and polymers is limited in their abilities to provide a hermetic and conductive package.

A low-temperature hermetic sealing method suitable for a MEMS device is suggested in “Low Temperature Hermetic Sealing Method Having Passivation Layer,” Kim et al., U.S. Patent Application 2003/0104651 published Jun. 5, 2003. The involved method requires depositing a junction layer, a wetting layer, and a solder layer on a prepared lid frame; depositing a first protection layer for preventing oxidation on the solder layer and forming a lid; preparing a package base on which a device is disposed, and in which a metal layer and a second protection layer are formed around the device; and assembling the lid and the package base, followed by heating and sealing. The protection layer is laminated on the solder layer that is formed by the lid, thereby preventing oxidation without using a flux.

A potential solution to the high cost of die-level packaging is wafer-level or wafer-scale packaging where MEMS-based devices can be encapsulated before the dicing of the wafer. Wafer-level packaging offers protection against micro-contamination from particles and dicing slurry while being processed like a standard semiconductor chip, and can eliminate the need for dedicated equipment or processes for dicing, mounting and molding procedures inside cleanrooms. An example of a wafer-level package having a hermetically sealed chamber covered by a transparent window is described in “Light Emitting Semiconductor Package,” Silverbrook, U.S. Patent Application 2002/0088988 published Jul. 11, 2002. Transparent molded themoplastic caps are bonded to the surface of the chips on a wafer to encapsulate the devices before they are diced into individual packages.

While the packages and packaging methods described above have heretofore produced packages for micro-devices, the relatively high cost of manufacturing is a significant obstacle to their widespread application. Packages for movable components of MEMS devices need highly reliable, large-volume, low-cost manufacturing and packaging processes in order to be economically feasible. In the case of movable MEMS or MOEMS devices such as a micromirror assembly, the cap and the cavity of the package should be deep enough to accommodate relatively large deflections of the devices. Many of the aforementioned integrated packages have insufficient height to accommodate movable MEMS devices such as actuated micromirrors in an optical MEMS switch.

Thus, a need exists in the semiconductor industry for a cost-effective, highly reliable, high-volume, wafer-scale packaging process for creating a windowed package having a large sealed protective cavity for a movable MEMS device such as a micromirror. Such a process should provide low-temperature processing and allow singulation after encapsulation. Package materials should provide electrostatic discharge protection, and preferably, the materials and packaging processes are compatible with complementary metal-oxide semiconductor (CMOS) devices and processes. The wafer-level packaging process should provide a controlled environment in a sealed cavity, protecting sensitive MEMS devices from air currents, fluctuating temperatures, electrostatic discharge and charge buildup, particle contamination, and other adverse conditions.

### SUMMARY OF THE INVENTION

A first aspect in accordance with the present invention is a wafer-level package for a micromirror array. The wafer-level package includes a substrate having a substrate surface, a plurality of actuatable micromirrors coupled to the substrate surface, and an optical window attached to the substrate surface to form at least one sealed cavity between an inner surface of the optical window and the substrate surface. A beam of light transmitted through the optical window is redirected by at least one actuatable micromirror within the sealed cavity.

Another aspect in accordance with the present invention is a method of packaging an array of actuatable micromirrors. A substrate having a substrate surface and a plurality of actuatable micromirrors coupled to the substrate surface is provided. An optical window is provided and attached to the substrate surface to form at least one sealed cavity between an inner surface of the optical window and the substrate surface. A beam of light transmitted through the optical window is redirected by at least one actuatable micromirror within the sealed cavity.

Another aspect in accordance with the present invention is a micromirror assembly. The micromirror assembly includes a substrate having a substrate surface, a plurality of actuatable micromirrors coupled to the substrate surface, and an optical window attached to the substrate surface to form a sealed cavity between an inner surface of the optical window and the substrate surface. A beam of light transmitted through the optical window is redirected by at least one actuatable micromirror within the sealed cavity.

Another aspect in accordance with the present invention is a system for directing a beam of light including a packaged micromirror array. The packaged micromirror array includes a substrate having a substrate surface, a plurality of actuatable micromirrors coupled to the substrate surface, and an optical window attached to the substrate surface to form at least one sealed cavity between an inner surface of the optical window and the substrate surface. A beam of light transmitted through the optical window is redirected by at least one actuatable micromirror within the sealed cavity.

### BRIEF DESCRIPTION OF THE DRAWINGS

The aforementioned, and other features and advantages of the invention will become further apparent from the following detailed description of the presently preferred embodiments, read in conjunction with the accompanying drawings. The detailed description and drawings are merely illustrative of the invention rather than limiting, the scope of the invention being defined by the appended claims and equivalents thereof. Various embodiments of the present invention are illustrated by the accompanying figures, the figures not necessarily drawn to scale, wherein:

FIG. 1 illustrates a cross-sectional view of a portion of a wafer-level package for a micromirror array, showing a packaged micromirror assembly in accordance with one embodiment of the current invention;

FIG. 2 illustrates a cross-sectional view of a micromirror assembly with cap reflectors on an optical window, in accordance with one embodiment of the current invention;

FIG. 3 illustrates a cross-sectional view of a micromirror assembly with cap reflectors on a cap lens, in accordance with one embodiment of the current invention;

FIG. 4 illustrates a cross-sectional view of a micromirror assembly with a transparent shim with cap reflectors, in accordance with one embodiment of the current invention;

FIG. 5a and FIG. 5b illustrate a top view with an expanded top view and a cross-sectional view of a wafer-level package for a micromirror array, in accordance with one embodiment of the current invention;

FIG. 6a, FIG. 6b, FIG. 6c, FIG. 6d, FIG. 6e and FIG. 6f show cross-sectional views corresponding to steps of a method for forming a molded recess in an optical window, in accordance with one embodiment of the current invention; and

FIG. 7 is a flow chart of a method of packaging an array of actuatable micromirrors, in accordance with one embodiment of the current invention.

### DETAILED DESCRIPTION OF THE INVENTION

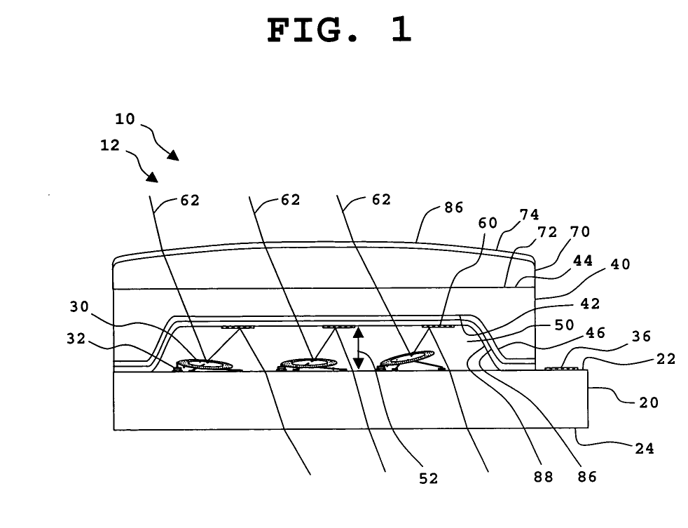

FIG. 1 illustrates a cross-sectional view of a packaged micromirror assembly, in accordance with one embodiment of the present invention. Packaged micromirror assembly 10 is diced or otherwise cut from a wafer-level package 12 for an array of actuatable micromirrors 30 or other devices. Packaged micromirror assembly 10 includes a substrate 20 having a substrate surface 22, a plurality of actuatable micromirrors 30 coupled to substrate surface 22, and an optical window 40 attached to substrate surface 22. Optical window 40 and substrate surface 22 cooperate to form one or more sealed cavities 50 between an inner surface 42 of optical window 40 and substrate surface 22. Inner surface 42 of optical window 40 faces sealed cavity 50, and may include additional layers such as an anti-reflective layer 86, a transparent conductive layer 88, or a combination thereof. Optical window 40, when attached to substrate surface 22, forms a lid or cap over actuatable micromirrors 30 or other devices contained within sealed cavity 50.

A beam of light 62 such as a focused beam of infrared, visible or ultraviolet light that is transmitted through optical window 40 may be redirected by one or more actuatable micromirrors 30 within sealed cavity 50. Beam of light 62 may travel in either direction through optical window 40. In one embodiment, beam of light 62 is directed through optical window 40 into sealed cavity 50 and redirected back through optical window 40 in a direction controlled by an associated micromirror 30. In another embodiment, beam of light 62 traversing through optical window 40 is redirected by an associated micromirror 30 onto a portion of a cap reflector 60, and then reflected through substrate 20. In another embodiment, beam of light 62 traverses through substrate 20, strikes a portion of cap reflector 60, and then is redirected by associated micromirror 30 through optical window 40. In a system for directing a beam of light, one or more micromirror assemblies 10 may be used to control one or more beams of light 62. Optical window 40 may be transparent in the visible spectrum to allow viewing of actuatable micromirrors 30 in sealed cavity 50.

Substrate 20 comprises, for example, a silicon wafer, a glass wafer, a semiconductor wafer, a silicon-on-insulator wafer, or other suitable substrate for one or more actuatable micromirrors 30. Actuatable micromirrors 30 are formed, for example, on or in substrate surface 22 of substrate 20. For example, one or more actuatable micromirrors 30 are coupled to substrate surface 22 with least one micromirror actuator 32 such as a vertical comb-drive electrostatic actuator. Micromirror actuator 32 positions actuatable micromirror 30 into a desired orientation based on control signals applied to micromirror actuator 32. In one example, each actuatable micromirror 30 in an array is coupled to substrate 20 with a trio of vertical comb drive electrostatic actuators attached at equally spaced circumferential points around actuatable micromirror 30. Other mechanical elements such as torsional springs, flexures, beams and connectors may additionally or alternatively be used to couple actuatable micromirror 30 to substrate 20. Electrical bond pads 36 on substrate 20 allow control signals to be electrically communicated to micromirror actuators 32. Electrical traces carry the control signals from electrical bond pads 36 into sealed cavity 50 and to actuatable micromirrors 30.

An exemplary actuatable micromirror 30 includes a freestanding single-crystal silicon, thin-film polycrystalline silicon, or deposited silicon nitride structure having a reflective metal film or a dielectric stack deposited on a mirror plate. These reflective metal films such as gold, silver, rhodium, platinum, copper or aluminum typically have a thickness ranging from about 20 nm to about 2000 nm. In one example, actuatable micromirrors 30 are fabricated from surface-micromachined polycrystalline silicon (polysilicon) or amorphous silicon. In conventional surface-micromachining processes, alternate structural layers of polysilicon and sacrificial spacer layers of silicon dioxide are deposited on bulk silicon or silicon-on-insulator (SOI) wafers. The alternating polysilicon and oxide layer pairs deposited on substrate 20 may be electrically isolated from substrate 20 with a thin layer of silicon nitride or silicon dioxide. The layers are patterned using photolithographic processes and are selectively etched to form microstructures such as a micromirror. Cuts can be made through the oxide layers and filled with polysilicon to anchor the upper structural layers to underlying structural layers or to substrate 20. After the buildup process, the sacrificial oxide layers are removed using various techniques such as hydrofluoric acid release etching, which frees a device from substrate 20 and allows the device such as micromirror 30 to move relative to substrate 20. Micromirror actuators 32 can be formed, for example, at the same time as actuatable micromirrors 30 using the same or similar layers.

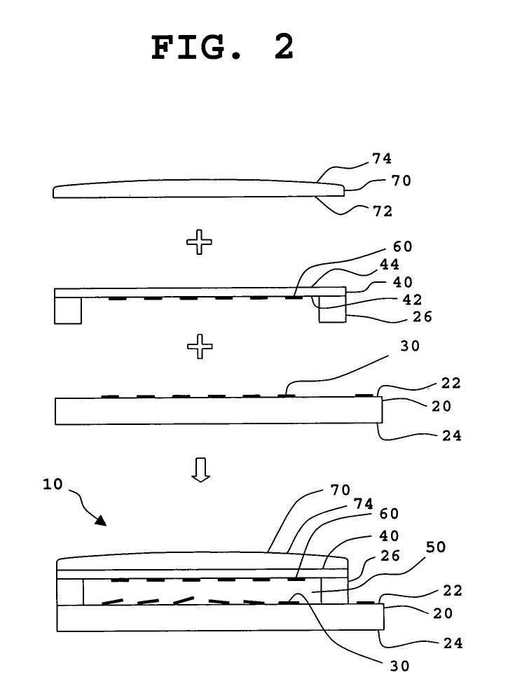

Optical window 40 is attached to substrate surface 22 of substrate 20 directly or through a spacer 26 such as a spacer wafer or a plated spacer, as described in more detail with respect to FIGS. 2-4. Spacer 26 may be plated onto either substrate 20 or optical window 40. Optical window 40 comprises, for example, a silicon wafer, a quartz wafer, a glass wafer, or other suitable window material such as Eagle2000™ from Corning, Inc. of Toledo, Ohio or an alkali-free borosilicate glass such as AF45 from Schott North America, Inc., of Elmsford, N.Y. Optionally, recesses may be formed in optical window 40 by etching, embossing, molding, or other suitable forming technique to serve as a cap over actuatable micromirrors 30 when optical window 40 is attached to substrate surface 22 of substrate 20. For example, optical window 40 has one or more molded recesses 46. When optical window 40 is attached to substrate 20, molded recess 46 forms at least a portion of sealed cavity 50.

Spacer 26 may be positioned between inner surface 42 of optical window 40 and substrate surface 22 of substrate 20 to increase a cavity height 52 of sealed cavity 50. To allow suitable travel of actuatable micromirrors 30, sealed cavity 50 may have cavity height 52 in excess of, for example, 100 micrometers.

Optical window 40 is attached either directly to or via a spacer 26 to substrate surface 22 of substrate 20 with, for example, a solder bond, a thermocompression bond, or other wafer-to-wafer bond such as a eutectic bond, a glass frit bond, a polymeric bond, or an adhesive bond. Solder systems such as 80/20 gold/tin, 95.5/3.8/0.7 tin/silver/copper, or indium-based materials may be used for solder bonding to substrate 20 with a corresponding seal region comprising, for example, aluminum/silicon/copper, nickel, palladium, or electroless indium. Optical window 40 may be attached to substrate surface 22 via a spacer 26 such as a plated spacer or a spacer wafer between inner surface 42 of optical window 40 and substrate surface 22. The plated spacer comprises, for example, electroless or electroplated nickel; titanium; or electrolytic or electroless indium. A layer of titanium or aluminum may serve as an adhesion layer under the plated spacer. The plated spacer may be capped with a layer of palladium, platinum or gold to prevent oxidation of spacer materials such as nickel.

One or more cap reflectors 60 may be disposed on inner surface 42 of optical window 40 to reflect beams of light 62. Cap reflectors 60 comprise highly reflective material such as a metal or a dielectric stack. Cap reflectors 60 may be configured as an array of strips corresponding to arrays of actuatable micromirrors 30; as an array of square, round, elliptical, or rectangular reflectors; as an opaque reflector with locally clear regions; or as another desired configuration. Alternatively, cap reflectors 60 may be disposed on an outer surface 44 of optical window 40 opposite sealed cavity 50. Cap reflectors 60 may be disposed on inner surface 42 of optical window 40 with other layers such as anti-reflective coating 86 or transparent conductive layer 88 positioned in between.

When used, a cap lens 70 may be attached to outer surface 44 of optical window 40 opposite sealed cavity 50. Cap lens 70 is used, for example, to refractively redirect beams of light 62 to a desired direction such as a common focal point when each actuatable micromirror 30 in an array are in a quiescent, non-actuated condition. One or more cap reflectors 60 may be disposed on a surface 72 of cap lens 70 between cap lens 70 and optical window 40.

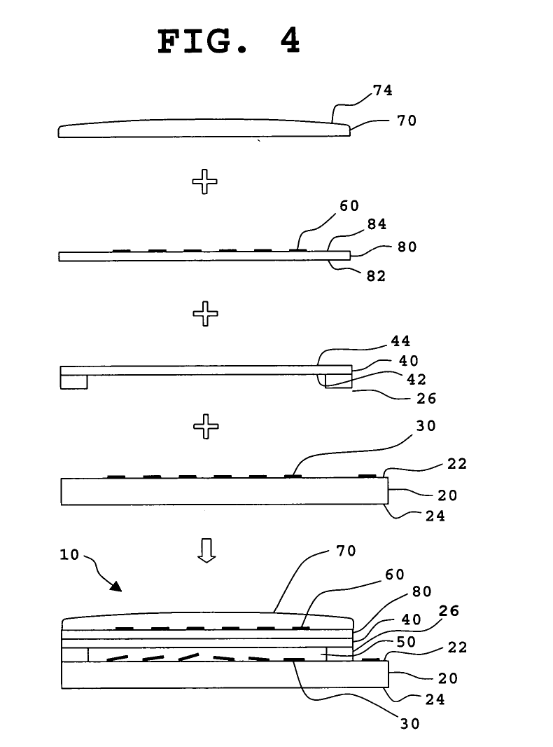

A transparent shim 80, as shown in FIG. 4, may be positioned between cap lens 70 and optical window 40. One or more cap reflectors 60 may be disposed on an inner surface 82 or an outer surface 84 of transparent shim 80.

Anti-reflective coatings may be used to minimize inadvertent reflections at interfaces between dissimilar optical materials, such as between glass and air. An anti-reflective coating 86 may be disposed on inner surface 42 of optical window 40. Exemplary reflective coatings 86 include a deposited layer of silicon nitride on optical window 40 made of silicon or a deposited layer of magnesium fluoride for optical window 40 made of glass. Additionally or alternatively, an anti-reflective coating 86 may be disposed on outer surface 44 of optical window 40 opposite sealed cavity 50. When cap lens 70 is used, anti-reflective coating 86 may be disposed on an outer surface 74 of the attached cap lens 70. Anti-reflective coatings, not shown for clarity, may also be used on substrate surface 22 and on a surface 24 of substrate 20 opposite substrate surface 22 to minimize optical loss of beams of light 62 traversing substrate 20.

To minimize effects such as electrostatic discharge or charge buildup, a transparent conductive layer 88 may be disposed on inner surface 42 of optical window 40. Transparent conductive layer 88, such as indium-tin-oxide (ITO), may be electrically connected to substrate 20 or to a portion thereon such as an electrical trace when optical window 40 is attached to substrate 20.

Packaged micromirror assembly 10 may be used in a fiber optic switch, an optical cross-connect switch, an optical scanner, a projection or display device, a sensor, a data storage device, an imaging array, or other systems for directing one or more beams of light 62. The system may include one or more packaged micromirror assemblies. Optical systems may include arrays of MEMS devices, each device having actuatable micromirror 30 that is individually controllable to reflect light in desired directions. Each packaged micromirror assembly 10 includes substrate 20 with substrate surface 22, a plurality of actuatable micromirrors 30 coupled to substrate surface 22, and optical window 40 attached to substrate surface 22 that forms at least one sealed cavity 50 between inner surface 42 of optical window 40 and substrate surface 22. One or more beams of light 62 may be directed to or from one or more actuatable micromirrors 30, transmitted through optical window 40 before or after striking actuatable micromirrors 30, and redirected by actuatable micromirrors 30 within sealed cavity 50. Each actuatable micromirror 30 may be coupled to substrate 20 with one or more micromirror actuators 32 such as a vertical comb-drive electrostatic actuator.

FIG. 2 illustrates a cross-sectional view of a micromirror assembly 10 with cap reflectors 60 on an optical window 40, in accordance with one embodiment of the present invention. In this embodiment, cap reflectors 60 are disposed on an inner surface 42 of optical window 40. A spacer 26 is plated or otherwise formed on inner surface 42 of optical window 40, positioned between optical window 40 and a substrate surface 22 of a substrate 20. Optical window 40 with spacer 26 is attached to substrate 20 having one or more actuatable micromirrors 30 coupled to substrate surface 22 of substrate 20. An inner surface 72 of an optional cap lens 70 may be attached to an outer surface 44 of optical window 40. When assembled, optical window 40 attaches to substrate surface 22 with a spacer 26 to form a sealed cavity 50 between inner surface 42 of optical window 40 and substrate surface 22 with actuatable micromirrors 30 contained therein. Cap lens 70 is attached to outer surface 44 of optical window 40 opposite sealed cavity 50. Cap reflectors 60 are positioned on inner surface 42 of optical window 40. Anti-reflective coatings, not shown, may be additionally disposed on inner surface 42 of optical window 40, on an outer surface 74 of cap lens 70, on substrate surface 22, and on surface 24 of substrate 20. When cap lens 70 is not used, an anti-reflective coating may be disposed on outer surface 44 of optical window 40. A transparent conductive layer, not shown, may additionally be disposed on inner surface 42 of optical window 40. A transparent conductive layer may be selectively disposed on substrate surface 22 of substrate 20.

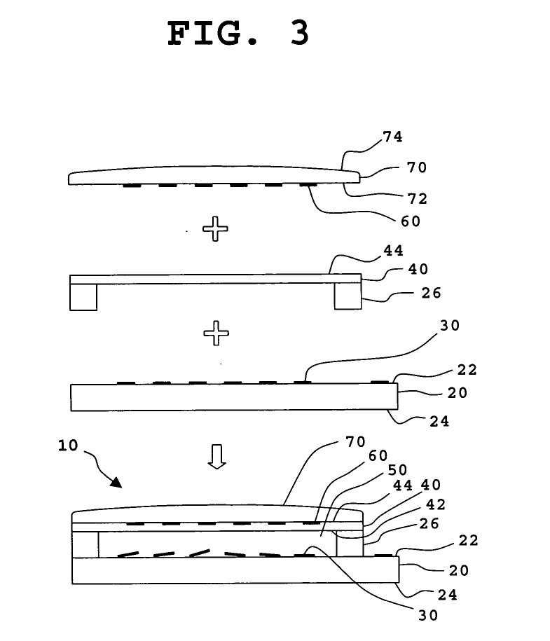

FIG. 3 illustrates a cross-sectional view of a micromirror assembly 10 with cap reflectors 60 on a cap lens 70, in accordance with one embodiment of the present invention. An array of cap reflectors 60 is disposed on a surface 72 of cap lens 70. Cap lens 70 is attached to an optical window 40 having a spacer 26. An optically transparent adhesive may be used to attach cap lens 70 to optical window 40.

Optical window 40 with spacer 26 is attached to a substrate surface 22 of a substrate 20. Micromirror assembly 10 has a plurality of actuatable micromirrors 30 coupled to substrate surface 22 of substrate 20. Optical window 40 with or without cap lens 70 is attached to substrate surface 22 to form a sealed cavity 50 between an inner surface 42 of optical window 40 and substrate surface 22. Although not shown, anti-reflective coatings may optionally be disposed on outer surface 74 of cap lens 70, on inner surface 42 of optical window 40, on substrate surface 22, and on surface 24 of substrate 20. When cap lens 70 is not used, an anti-reflective coating may be disposed on outer surface 44 of optical window 40. A transparent conductive layer, also not shown, may be disposed on inner surface 42 of optical window 40 and optionally on selective portions of substrate surface 22.

In another embodiment, cap reflectors 60 are positioned on an outer surface 44 of optical window 40 opposite sealed cavity 50 in lieu of cap reflectors 60 on surface 72 of cap lens 70.

FIG. 4 illustrates a cross-sectional view of a micromirror assembly 10 with a transparent shim 80 having cap reflectors 60, in accordance with one embodiment of the present invention. Transparent shim 80, comprising a glass or other suitably transparent material, has one or more cap reflectors 60 disposed on an inner surface 82 or on an outer surface 84 of transparent shim 80. Transparent shim 80 may be attached to optical window 40 using suitable glue, adhesive or lens bonding agent. The thickness of transparent shim 80 may be selected to achieve the desired distance between actuatable micromirrors 30 and cap reflectors 60. Because the total thickness is limited, the handling of substrate 20 with attached optical window 40 is eased when using conventional wafer handling equipment prior to attachment of transparent shim 80 and optional cap lens 70. Visible optical inspection of actuatable micromirrors 30 or other devices is possible prior to attachment of cap lens 70 or transparent shim 80. Cap lens 70 may distort the view of the devices and opaque cap reflectors 60 may obscure the view of the devices.

Cap lens 70 may be attached to outer surface 84 of transparent shim 80, prior to or after attachment of transparent shim 80 to optical window 40. Optical window 40 with spacer 26 is attached to a substrate surface 22 of substrate 20 having one or more actuatable micromirrors 30 coupled to substrate surface 22. Cap lens 70 and transparent shim 80 may be attached to optical window 40 prior to or after attachment of optical window 40 to substrate 20.

When assembled, micromirror assembly 10 includes optical window 40 attached to substrate surface 22 to form a sealed cavity 50 between inner surface 42 of optical window 40 and substrate surface 22. Transparent shim 80 is positioned on an outer surface 44 of optical window 40 opposite sealed cavity 50. One or more actuatable micromirrors 30 coupled to substrate surface 22 are contained within sealed cavity 50.

In the example shown, cap reflectors 60 are positioned between cap lens 70 and transparent shim 80. Alternatively, cap reflectors 60 may be positioned between transparent shim 80 and outer surface 44 of optical window 40. Anti-reflective coatings, not shown, may be additionally disposed on an inner surface 42 of optical window 40, on an outer surface 74 of cap lens 70, on at least a portion of substrate surface 22 of substrate 20, on surface 24 of substrate 20, or on outer surface 44 of optical window 40 when cap lens 70 is not used. A transparent conductive layer, not shown, may also be disposed on inner surface 42 of optical window 40 or on substrate surface 22.

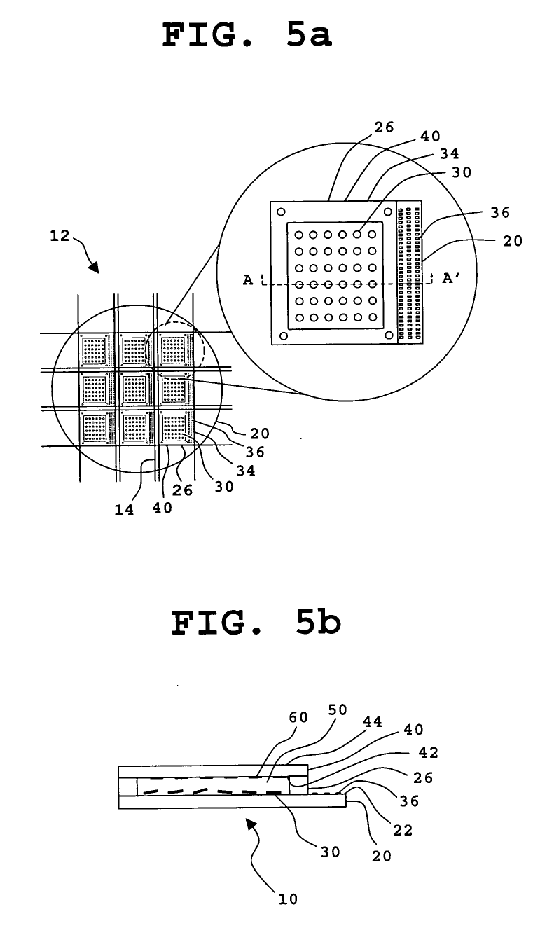

FIG. 5a and FIG. 5b illustrate a top view with an expanded top view and a cross-sectional view of a wafer-level package 12 for a micromirror array, in accordance with one embodiment of the present invention. Wafer-level package 12 includes a substrate 20 such as a silicon wafer having a substrate surface 22, a plurality of actuatable micromirrors 30 coupled to substrate surface 22, and an optical window 40 attached to substrate surface 22 that forms a plurality of sealed cavities 50 between an inner surface 42 of optical window 40 and substrate surface 22. Actuatable micromirrors 30 within wafer-level package 12 may be coupled to substrate surface 22 with at least one micromirror actuator such as a vertical comb drive electrostatic actuator. One or more beams of light transmitted through optical window 40 are redirected by at least one actuatable micromirror 30 within sealed cavity 50. Optical window 40 comprises, for example, a glass wafer or a silicon wafer. A spacer 26 comprising, for example, a spacer wafer or a plated spacer on either optical window 40 or on substrate surface 22 of substrate 20 may be included to provide the desired separation between optical window 40 and substrate 20 and to allow for full travel of actuatable micromirrors 30 within sealed cavity 50. With wafer-level packaging, hermetic seals may be created around one or more micromirror die 34 at the same time.

Shown prior to dicing, substrate 20 contains micromirror die 34 with actuatable micromirrors 30 and electrical bond pads 36. Optical window 40 is attached to substrate 20 at the wafer level prior to dicing. Spacer 26 between optical window and substrate 20 is plated onto either substrate 20 or optical window 40, or is attached to substrate 20 as a spacer wafer. When diced, individual micromirror assemblies 10 are formed. Dicing channels or streets 14 between micromirror die 34 are provided to allow for dicing or sawing between micromirror die 34.

Providing singulation after encapsulation in this manner has significant advantages over conventional processes. By encapsulating before dicing, the microstructures, including the movable MEMS, are protected from electrostatic discharge and charge build up, particle contamination, damage due to handling, and other packaging processes. The process in accordance with the present invention is thus a highly reliable, high-volume, low-cost manufacturing and packaging processes that is more economically advantageous than conventional processes that dice the substrate prior to encapsulation.

In the expanded portion of FIG. 5a, actuatable micromirrors 30 are visible through optical window 40. Optical window 40 is attached to substrate 20 with spacer 26. Provision is made for electrical connection such as wirebonding to electrical bond pads 36. Electrical bond pads 36 are connected by electrical traces (not shown for clarity) to actuators on the surface of substrate 20 that are used to position actuatable micromirrors 30. Vias, reference marks and other features may be included to aid in alignment, bonding and dicing.

In FIG. 5b, a cross-sectional view along line A-A′ through the expanded portion of packaged micromirror assembly 10 of FIG. 5a shows a sealed cavity 50 between optical window 40 and substrate 20, with an array of actuatable micromirrors 30 within sealed cavity 50. Cap reflectors 60, visible in the cross-sectional view, are optionally added to wafer-level package 12 and are positioned, for example, on inner surface 42 of optical window 40. Alternatively, cap reflectors 60 may be located on an outer surface 44 of optical window 40 opposite sealed cavity 50. Anti-reflective coatings, not shown for clarity, may be added to appropriate surfaces of optical window 40 and substrate 20. A transparent conductive layer, also not shown for clarity, may be located on inner surface 42 of optical window 40 or on substrate surface 22. Additional optical elements such as a cap lens or a cap lens array may be added at the wafer level or to singulated micromirror assemblies 10.

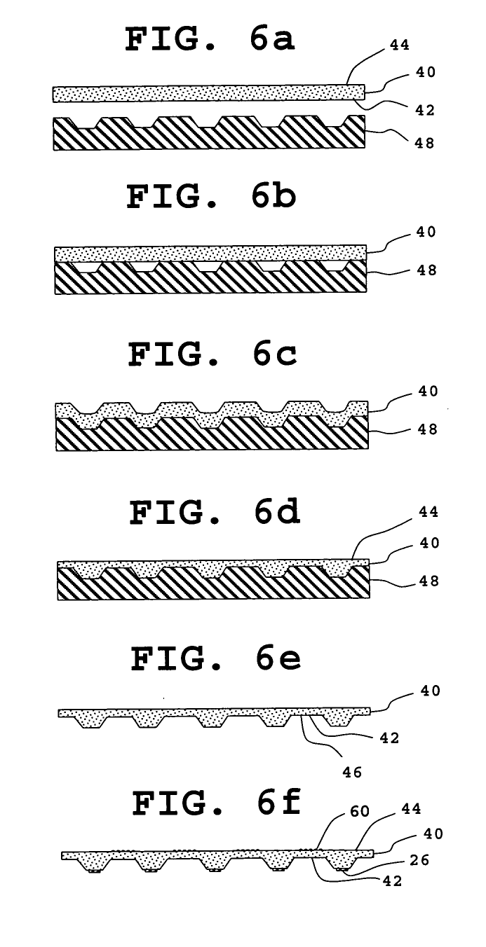

FIG. 6a, FIG. 6b, FIG. 6c, FIG. 6d, FIG. 6e, and FIG. 6f show cross-sectional views corresponding to steps of a method for forming a molded recess in an optical window, in accordance with one embodiment of the present invention.

An optical window 40 with molded recesses is formed, for example, by positioning a glass wafer or sheet having an inner surface 42 and an outer surface 44 opposite inner surface 42 against a suitable mold 48 having one or more patterns corresponding to the desired molded recesses in optical window 40, as shown in FIG. 6a. Mold 48 comprises, for example, tool steel, ceramic, Zerodur®, silicon, graphite, or other suitable material.

Optical window 40 is positioned against mold 48, as shown in FIG. 6b. After heating, optical window 40 softens and forms against mold 48, as shown in FIG. 6c. Vacuum or pressure may be applied to assist in forming optical window 40 against mold 48. At this point, optical window 40 is optionally planarized, for example, by lapping, grinding or polishing, to form a relatively flat outer surface 44, as shown in FIG. 6d. Optical window 40 is removed from mold 48 to reveal molded recesses 46 in inner surface 42 of optical window 40, as shown in FIG. 6e. Portions of optical window 40 such as outer surface 44, protruding portions opposite outer surface 44, or interior surface 42 within molded recesses 46 may be polished, lapped, ground, or otherwise smoothed as needed.

Cap reflectors 60 may be disposed on outer surface 44 of optical window 40 or on inner surface 42 using, for example, thin film depositions of one or more metal or dielectric layers, along with lithographic techniques to pattern and etch the deposited materials, as shown in FIG. 6f. Anti-reflective coatings and transparent conductive layers may be added onto inner surface 42 or outer surface 44 of optical window 40. Spacers 26 or thin layers of materials that enable soldering such as nickel, indium, or tin-based materials may be plated onto portions of optical window 40 opposite outer surface 44 to add additional cavity height or to provide a solderable seal region for hermetic attachment. Thin titanium or aluminum layers may serve as an adhesion layer. A layer of palladium, platinum, or gold may be used to cap spacer 26 or the solderable seal region to prevent oxidation prior to bonding.

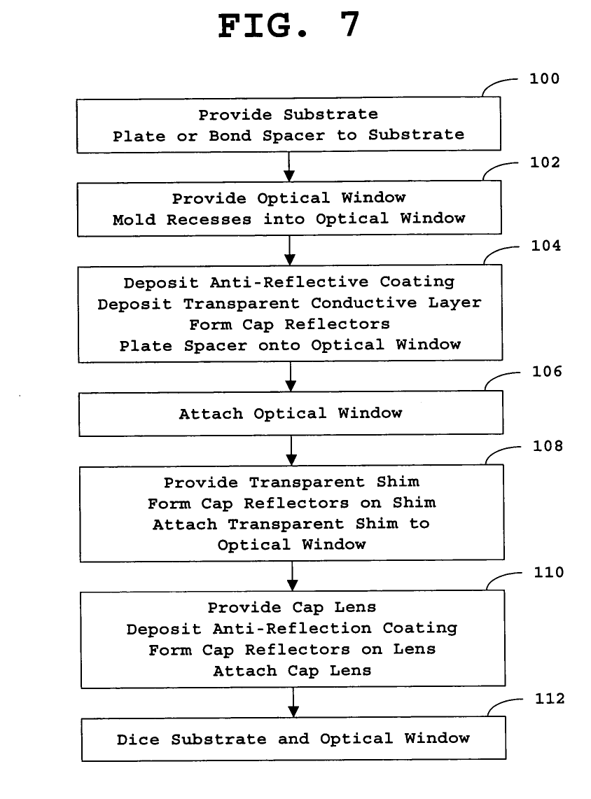

FIG. 7 is a flow chart of a method of packaging an array of actuatable micromirrors, in accordance with one embodiment of the present invention.

A substrate is provided, as seen at block 100. The substrate, such as a silicon wafer, a silicon-on-insulator wafer, or a glass wafer, has a plurality of actuatable micromirrors coupled to a surface of the substrate.

The substrate may optionally have a spacer attached to a surface of the substrate. For example, a silicon or metal spacer wafer with an array of holes corresponding to groups or arrays of actuatable micromirrors may be attached to the substrate. Alternatively, a spacer may be plated onto the substrate surface prior to attaching the optical window to the substrate surface.

An optical window is provided, as seen at block 102. The provided optical window comprises, for example, a glass wafer or a silicon wafer of similar diameter as the substrate. The optical window may have, for example, one or more recesses molded into the optical window to form at least a portion of the sealed cavity.

The optical window may be enhanced with additions of one or more anti-reflective coatings, transparent conductive layers, cap reflectors, plated spacers, solderable seal regions, or plated attachment materials, as seen at block 104. For example, an anti-reflective coating such as a thin layer of magnesium fluoride may be deposited on the inner surface of the optical window. Alternatively or in addition to, an anti-reflective coating may be deposited on a surface of the optical window opposite the sealed cavity.

A transparent conductive layer such as indium-tin-oxide (ITO) may be deposited on the inner surface of the optical window. The transparent conductive layer provides electrical connection to the substrate or to one or more electrical pads on the substrate when the optical window is attached to the substrate to minimize, for example, build-up of charge on the inner surface of the optical window.

One or more cap reflectors may be formed on the inner surface of the optical window or on a surface opposite the inner surface prior to attaching the optical window to the substrate surface. The size, geometry and spacing between the cap reflectors correspond with the positions and geometry of the actuatable micromirrors coupled to the substrate surface.

In cases where a spacer is needed, a spacer may be plated onto the inner surface of the optical window prior to attaching the optical window to the substrate surface. The plated spacer increases the cavity height within the sealed cavity, which gives sufficient clearance for the actuatable micromirrors to move after the optical window is attached to the substrate surface. Alternatively, the spacer may be plated onto the substrate surface. For example, spacers or thinner solderable seal regions may be plated onto the optical window or onto the substrate surface using one or more layers of titanium, electroless nickel, and indium. Solderable materials may be plated on the spacer. A layer of titanium or aluminum may serve as an adhesion layer under the plated spacer or solderable material. An additional layer of palladium, platinum or gold may be added to reduce or eliminate oxidation of the solderable materials.

The optical window is attached to the substrate surface to form at least one sealed cavity between an inner surface of the optical window and the substrate surface, as seen at block 106. The optical window may be attached to the substrate surface with, for example, a solder bond, a thermocompression bond, or other wafer-to-wafer bond such as a eutectic bond, a glass frit bond, a polymeric bond, or an adhesive bond. For example, the optical window and the substrate are aligned, pressed together, and heated while pressure continues to be applied to complete the wafer-to-wafer bond. Soldering of the optical window onto the substrate surface may be done in a controlled gaseous ambient to provide a proper environment for operation of the actuatable micromirrors within the sealed cavity.

An optional transparent shim may be attached between the cap lens and the optical window, as seen at block 108. The transparent shim comprises, for example, a glass wafer or a glass sheet to increase the distance between the actuatable micromirrors and the cap reflectors. One or more cap reflectors may be formed on one surface or the other of the transparent shim prior to or after attaching the transparent shim to the optical window.

An optional cap lens is provided, as seen at block 110. The cap lens may be configured as an individual lens element or as a coupled array of lens elements. An anti-reflective coating may be deposited on an outer surface of the cap lens. Additionally, one or more cap reflectors may be formed on a surface of the cap lens between the cap lens and the optical window.

The cap lens may be attached to the optical window on a surface opposite the sealed cavity using, for example, a suitable glue, adhesive or lens bonding agent applied to the cap lens or to a corresponding surface of the optical window.

The substrate with the attached optical window may be diced or otherwise sawed to singulate and form the packaged micromirror arrays, as seen at block 112. Alternatively, the cap lens may be attached to the packaged micromirror array after dicing. Similarly, the transparent shim may be attached to the packaged micromirror array after dicing. In configurations where the cap lens and the transparent shim are not needed, the cap lens attachment and transparent shim attachment steps are omitted accordingly. The singulated micromirror assemblies may be inspected visually, for example, through the optical window and electrically through actuation of the micromirrors with one or more control signals communicated to actuators within the sealed cavity.

While the embodiments of the invention disclosed herein are presently considered to be preferred, various changes and modifications can be made without departing from the spirit and scope of the invention. For example, the steps for assembling the wafer-level package may be made in an alternate order or with additional processing steps, as one skilled in the art would recognize. For example, other MEMS and non-MEMS devices including optical devices, optomechanical devices, mechanical devices, electromechanical devices, and electro-optical devices may be contained within the sealed cavity with or in lieu of the actuatable micromirrors. The scope of the invention is indicated in the appended claims, and all changes that come within the meaning and range of equivalents are intended to be embraced therein.

1. A wafer-level package for a micromirror array, the wafer-level package comprising:
a substrate comprising a wafer having a substrate surface;
a plurality of actuatable micromirrors coupled to the substrate surface; and
an optical window attached to the substrate surface to form at least one sealed cavity between an inner surface of the optical window and the substrate surface, wherein a beam of light transmitted through the optical window is redirected by at least one actuatable micromirror within the at least one sealed cavity.

2. The wafer-level package of claim 1, wherein the plurality of actuatable micromirrors is coupled to the substrate surface with at least one vertical comb drive electrostatic actuator.

3. The wafer-level package of claim 1, wherein the substrate comprises a silicon wafer.

4. The wafer-level package of claim 1, wherein the optical window comprises one of a glass wafer or a silicon wafer.

5. The wafer-level package of claim 1, wherein the at least one sealed cavity has a cavity height greater than 100 micrometers.

6. The wafer-level package of claim 1, wherein the optical window is attached to the substrate with one of a solder bond, a thermocompression bond, or a wafer-to-wafer bond.

7. The wafer-level package of claim 1, wherein the optical window comprises at least one molded recess to form at least a portion of the at least one sealed cavity.

8. The wafer-level package of claim 1, wherein the optical window is attached to the substrate surface via a spacer between the inner surface of the optical window and the substrate surface.

9. The wafer-level package of claim 8, wherein the spacer comprises plated nickel.

10. The wafer-level package of claim 1 further comprising:
at least one cap reflector disposed on the inner surface of the optical window.

11. The wafer-level package of claim 1 further comprising:
at least one cap reflector disposed on a surface of the optical window opposite the at least one sealed cavity.

12. The wafer-level package of claim 1 further comprising:
a cap lens attached to the optical window on a surface opposite the at least one sealed cavity.

13. The wafer-level package of claim 12 further comprising:
at least one cap reflector disposed on a surface of the cap lens between the cap lens and the optical window.

14. The wafer-level package of claim 12 further comprising:
a transparent shim positioned between the cap lens and the optical window.

15. The wafer-level package of claim 14 further comprising:
at least one cap reflector disposed on a surface of the transparent shim.

16. The wafer-level package of claim 1 further comprising:
an anti-reflective coating disposed on the inner surface of the optical window.

17. The wafer-level package of claim 1 further comprising:
an anti-reflective coating disposed on an outer surface of the optical window opposite the at least one sealed cavity.

18. The wafer-level package of claim 12 further comprising:
an anti-reflective coating disposed on an outer surface of the attached cap lens.

19. The wafer-level package of claim 1 further comprising:
a transparent conductive layer disposed on the inner surface of the optical window.

20. The wafer-level package of claim 1, wherein the optical window attached to the substrate surface forms a plurality of sealed cavities.

21. A wafer-level package for a micromirror array, the wafer-level package comprising:
a substrate comprising a wafer having a substrate surface;
a plurality of actuatable micromirrors coupled to the substrate surface; and
an optical window attached to the substrate surface to form a plurality of sealed cavities between an inner surface of the optical window and the substrate surface, wherein a beam of light transmitted through the optical window is redirected by at least one actuatable micromirror within one of the plurality of the sealed cavities.

22. A method of packaging an array of actuatable micromirrors, the method comprising:
providing a substrate comprising a wafer having a substrate surface and a plurality of actuatable micromirrors coupled to the substrate surface;
providing an optical window; and
attaching the optical window to the substrate surface to form at least one sealed cavity between an inner surface of the optical window and the substrate surface, wherein a beam of light transmitted through the optical window is redirected by at least one actuatable micromirror within the at least one sealed cavity.

23. The method of claim 22, wherein the provided optical window comprises one of a glass wafer or a silicon wafer.

24. The method of claim 22, wherein attaching the optical window to the substrate surface comprises forming one of a solder bond, a thermocompression bond, or a wafer-to-wafer bond between the optical window and the substrate surface.

25. The method of claim 22 further comprising:
molding at least one recess into the optical window to form at least a portion of the at least one sealed cavity.

26. The method of claim 22 further comprising:
plating a spacer onto the inner surface of the optical window prior to attaching the optical window to the substrate surface, wherein the plated spacer increases a cavity height within the at least one sealed cavity.

27. The method of claim 22 further comprising:
forming a cap reflector on the inner surface of the optical window or on a surface of the optical window opposite the at least one sealed cavity prior to attaching the optical window to the substrate surface.

28. The method of claim 22 further comprising:
attaching a cap lens to the optical window on a surface of the optical window opposite the at least one sealed cavity.

29. The method of claim 28 further comprising:
forming a cap reflector on a surface of the cap lens between the cap lens and the optical window.

30. The method of claim 28 further comprising:
attaching a transparent shim between the cap lens and the optical window.

31. The method of claim 30 further comprising:
forming a cap reflector on a surface of the transparent shim.

32. The method of claim 22 further comprising:
depositing an anti-reflective coating on the inner surface of the optical window.

33. The method of claim 22 further comprising:
depositing an anti-reflective coating on a surface of the optical window opposite the at least one sealed cavity.

34. The method of claim 28 further comprising:
depositing an anti-reflective coating on an outer surface of the cap lens.

35. The method of claim 22 further comprising:
depositing a transparent conductive layer on the inner surface of the optical window.

36. The method of claim 22 further comprising:
dicing the substrate and the attached optical window to form a plurality of packaged micromirror arrays.

37. A micromirror assembly, the micromirror assembly comprising:
a diced substrate having a substrate surface;
a plurality of actuatable micromirrors coupled to the substrate surface; and
an optical window attached to the substrate surface to form a sealed cavity between an inner surface of the optical window and the substrate surface, wherein the sealed cavity was formed prior to dicing of the substrate, wherein a beam of light transmitted through the optical window is redirected by at least one actuatable micromirror within the sealed cavity.

38. The micromirror assembly of claim 37, wherein each micromirror is coupled to the substrate with at least one vertical comb drive electrostatic actuator.

39. A system, the system comprising:
a wafer-level package for a micromirror array, the wafer-level package including a substrate having a substrate surface, a plurality of actuatable micromirrors coupled to the substrate surface, and an optical window attached to the substrate surface to form a plurality of sealed cavities between an inner surface of the optical window and the substrate surface; wherein a beam of light transmitted through the optical window is redirected by at least one actuatable micromirror within one of the plurality of sealed cavities.

40. The system of claim 39, wherein each micromirror is coupled to the substrate with at least one vertical comb drive electrostatic actuator.
